(19) United States
(12) Patent Application Publication
(10) Pub. No.: US 2006/0006529 A1
(43) Pub. Date: Jan. 12, 2006

(54) SEMICONDUCTOR PACKAGE AND METHOD FOR MANUFACTURING THE SAME

(76) Inventor: Min-Jer Lin, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/710,399

(22) Filed: Jul. 8, 2004

(51) Int. Cl. H01L 23/48

(52) U.S. Cl. 257/734

(57) ABSTRACT

A semiconductor package positioned on a first substrate includes a second substrate having a first surface and a second surface, a chip positioned on the first surface of the second substrate, a plurality of first bonding balls positioned on the second surface of the second substrate and arranged in a line along a first direction for connecting the second substrate to the first substrate, and at least a dummy bonding bar positioned on the second surface of the second substrate for connecting the second substrate to the first substrate and preventing the semiconductor package from inclining to one side.

### BACKGROUND OF INVENTION

1. Field of the Invention

The present invention relates to a semiconductor package, and more specifically, to a ball grid array (BGA) semiconductor package having a plurality of solder balls arranged in a single line.

2. Description of the Prior Art

Integrated circuit (IC) packages generally include PTH (pin through hole) types and SMT (surface mount technology) types. Since the SMT type package has advantages of a large number of I/O pins, high heat dissipation and a small size, the SMT type package has played an important role in the IC package industry. Additionally, the SMT type package adopts solder balls instead of leads, and the SMT type package usually includes a BGA package and a chip scale package (CSP), which can be regarded as an ultra small BGA package.

Please refer to FIG. 1 and FIG. 2. FIG. 1 is a bottom view of a prior art semiconductor package. FIG. 2 is a cross-sectional view along line 2-2′ of FIG. 1. As shown in FIG. 1 and FIG. 2, a semiconductor package 10 includes a substrate 12 having an upper surface 12a and a lower surface 12b, a chip 14 positioned on the upper surface 12a of the substrate 12, a plurality of bonding pads 18 positioned on the lower surface 12b of the substrate 12, and a plurality of solder balls 16 respectively positioned on the bonding pads 18. The chip 14 is an image sensor chip, such as a charge coupled device (CCD) or a CMOS image sensor device, and the chip 14 can be connected to the substrate 12 by using a wiring bonding method or a flip-chip method. Additionally, the semiconductor package 10 is electrically connected to a printed circuit board (PCB) 20 for forming a BGA package. Generally, the printed circuit board 20 includes a plurality of bonding pads (not shown), each of which is positioned between the printed circuit board 20 and each of the solder balls 16.

Due to the progress of the semiconductor technology, electronic devices in the chip 14 are made smaller and smaller so that the chip 14 is generally shrinking in size. Accordingly, a width W and a length L of the chip 14 are gradually reduced, such that dimensions of each solder ball 16 and a distance between two adjacent solder balls 16 have to be decreased. However, due to process limitations, the dimensions of each solder ball 16 and the distance between two adjacent solder balls 16 cannot be reduced without limitation. That is, dimensions of the chip 14 can be reduced until the lower surface 12b of the substrate 14 accommodates only a single row of solder balls 16. Nevertheless, as shown in FIG. 3, when the semiconductor package 10 is electrically connected to the printed circuit board 20 via the solder balls 16 arranged in a single line, the semiconductor package 10 on the printed circuit board 20 may incline to one side easily, which changes an incident angle between incident light and the image senor chip 14, thereby degrading sensing accuracy of the image senor chip 14.

### SUMMARY OF INVENTION

It is therefore a primary objective of the claimed invention to provide a semiconductor package for solving the above-mentioned problem.

According to the claimed invention, a semiconductor package is provided. The semiconductor package positioned on a first substrate includes a second substrate having a first surface and a second surface, a chip positioned on the first surface of the second substrate, a plurality of first bonding balls positioned on the second surface of the second substrate and arranged in a line along a first direction for connecting the second substrate to the first substrate, and at least a dummy bonding bar positioned on the second surface of the second substrate for connecting the second substrate to the first substrate and preventing the semiconductor package from inclining to one side.

It is an advantage over the prior art that the claimed invention provides at least one dummy bonding bar of the second surface of the second substrate, so that the semiconductor package can be effectively prevented from inclining to one side.

These and other objectives of the claimed invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a bottom view of a prior art semiconductor package.

FIG. 2 is a cross-sectional view along line 2-2′ of FIG. 1.

FIG. 3 is a cross-sectional view of a prior art semiconductor package having solder balls arranged in a single line.

FIG. 4 is a bottom view of a semiconductor package according to the first embodiment of the present invention.

FIG. 5 is a cross-sectional view along line 5-5′ of FIG. 4.

FIG. 6 is a cross-sectional view along line 6-6′ of FIG. 4.

FIG. 7 is a bottom view of a semiconductor package according to the second embodiment of the present invention.

FIG. 8 to FIG. 11 are schematic diagrams illustrating a method for manufacturing a semiconductor package according to the present invention.

FIG. 12 is a bottom view of a semiconductor package according to the third embodiment of the present invention.

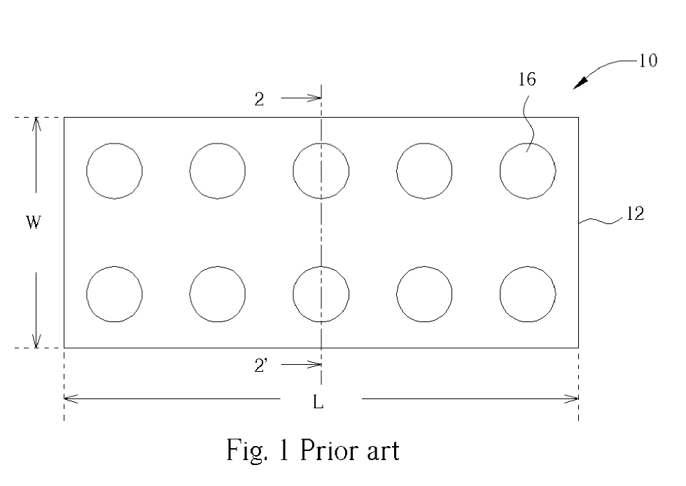

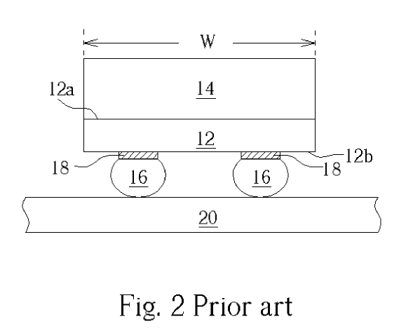

### DETAILED DESCRIPTION

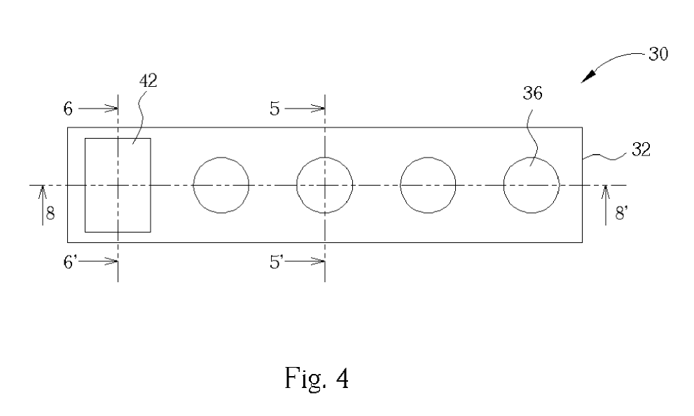

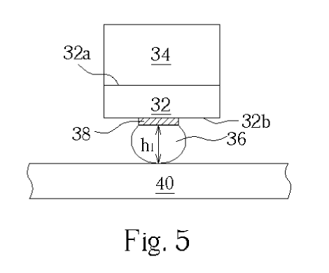

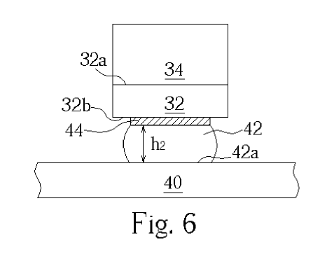

Please refer to FIG. 4 to FIG. 6. FIG. 4 is a bottom view of a semiconductor package according to the first embodiment of the present invention. FIG. 5 is a cross-sectional view along line 5-5′ of FIG. 4.FIG. 6 is a cross-sectional view along line 6-6′ of FIG. 4. As shown in FIG. 4 and FIG. 5, a semiconductor package 30 includes a substrate 32 having an upper surface 32a and a lower surface 32b, a chip 34 positioned on the upper surface 32a of the substrate 32, a plurality of bonding pads 38 positioned on the lower surface 32b of the substrate 32, and a plurality of bonding balls 36 respectively positioned on the bonding pads 38. The chip 34 is an image senor chip, such as a CCD or a CMOS image sensor chip, and the chip 34 can be connected to the substrate 12 by using a wiring bonding method or a flip-chip method. Additionally, the chip 34 has a rectangular shape, the bonding balls 36 are arranged in a line along a long side of the chip 34, and a length of a short side of the chip 34 is less than 1000 μm. The substrate 32 can be a build-up printed circuit board, a co-fired ceramic substrate, a thin-film deposited substrate or a glass substrate.

As shown in FIG. 5 and FIG. 6, the semiconductor package 30 further includes a dummy bonding pad 44 positioned on the lower surface 32b of the substrate 32, and a dummy bonding bar 42 positioned on the dummy bonding pad 44 and having a planar surface 42a. Additionally, a height h₂ of the dummy bonding bar 42 is approximately equal to a height h₁ of each bonding ball 36. Furthermore, the semiconductor package 30 is connected to a printed circuit board 40 via the bonding balls 36 and the dummy bonding bar 42 for forming a BGA package. The printed circuit board 40 usually includes a plurality of bonding pads (not shown), each of which is positioned between the printed circuit board 40 and each of the dummy bonding bar 42 and the bonding balls 36. The dummy bonding bar 42 and the bonding balls 36 are composed of tin (Sn).

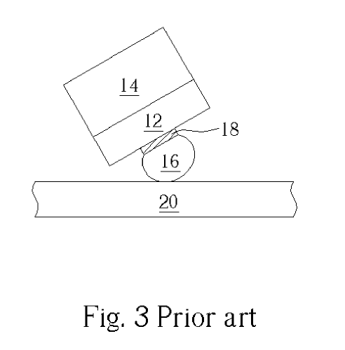

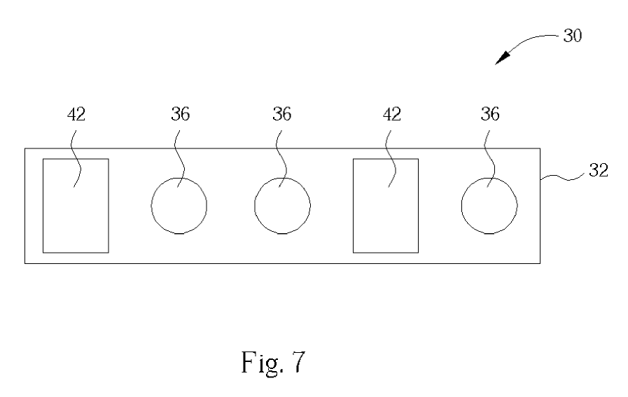

Since the dummy bonding bar 42 has the planar surface 42a, there is a surface contact between the dummy bonding bar 42 and the printed circuit board 40 when the surface 42a of the dummy bonding bar 42 is connected to the printed circuit board 40. Further, because the longest side of the dummy bonding bar 42 is approximately perpendicular to the long side of the chip 34, the semiconductor package 30 can be balanced on the printed circuit board 40, thereby preventing the semiconductor package 30 from inclining to one side. Additionally, a shape, a position, and an amount of the dummy bonding bar 42 are not limited to those shown in FIG. 3 and can be changed according to process requirements. Therefore, please refer to FIG. 7, which is a bottom view of a semiconductor package according to the second embodiment of the present invention. As shown in FIG. 7, a semiconductor package 30 includes a substrate 32, a plurality of bonding balls 36 positioned on the substrate 32, and two dummy bonding bars 42 positioned on the substrate 32 and among the bonding balls 36.

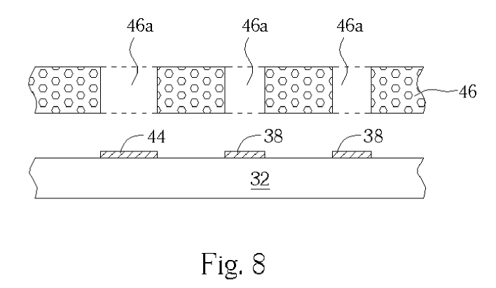

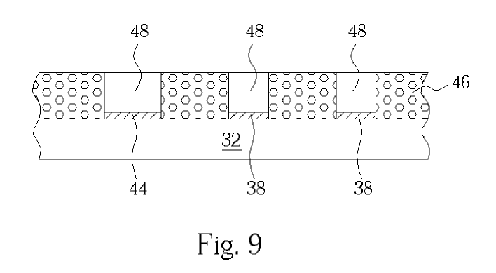

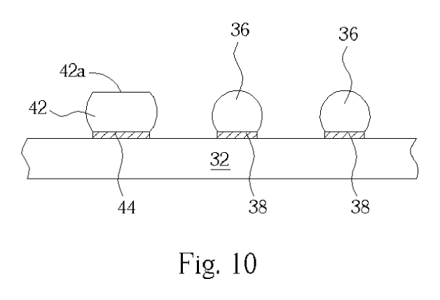

Please refer to FIG. 8 to FIG. 11. FIG. 8 to FIG. 11 are schematic diagrams illustrating a method for manufacturing a semiconductor package according to the present invention. Additionally, FIG. 8 to FIG. 11 are cross-sectional views along line 8-8′ of FIG. 4. As shown in FIG. 8, a substrate 32 is firstly provided. Then, a plurality of bonding pads 38 and a dummy bonding pad 44 are formed on the substrate 32 by using thin-film deposition processes, photolithographic processes and etching processes. Thereafter, a stencil plate 46 is provided and the stencil plate 46 has a plurality of openings 46a respectively corresponding to the bonding pads 38 and the dummy bonding pad 44. As shown in FIG. 9, the stencil plate 46 is put on the substrate 32 such that the bonding pads 38 and the dummy bonding pad 44 are exposed. After that, solder paste 48 is coated in the openings 46a of the stencil plate 46, and then, the stencil plate 46 is separated from the substrate 32. As shown in FIG. 10, a thermal treatment process is performed on the substrate 32 for melting the solder paste 48, thus forming the bonding balls 36 and the dummy bonding bar 42. Additionally, the solder paste 48 can be a tin (Sn) based metal containing lead (Pb) or a tin based metal that contains no lead, and the solder paste 48 has a melting point between 180° C. and 235° C. Furthermore, the bonding pads 38 and the dummy bonding pad 44 are composed of a tin based metal, which contains no lead and has a melting point between 180° C. and 235° C. In another embodiment of the present invention, the stencil plate 46 can be replaced with a screen sheet.

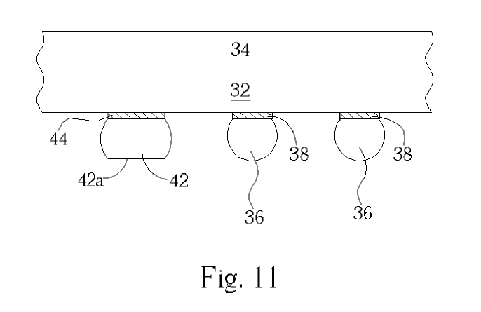

Finally, the chip 34 is connected to the substrate 32 by using a wiring bonding method or a flip-chip method, as shown in FIG. 11. In addition, the bonding balls 36 and the dummy bonding bar 42 can be made by using an electroplating method, an electroless plating method, an evaporation method or a laser ball shooter.

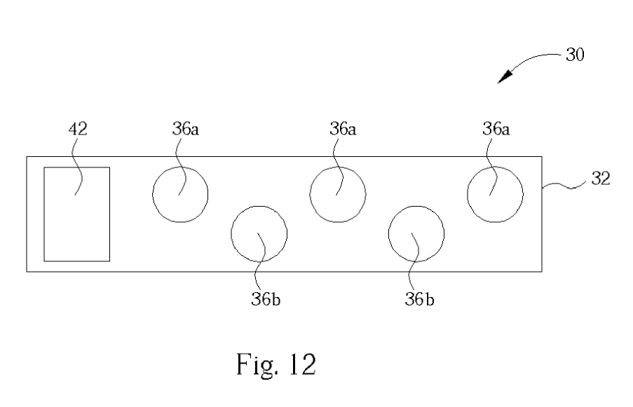

In addition, the structure of the semiconductor package 30 is not limited to those shown in FIGS. 4-6, and the following description will introduce other embodiments of the present invention. Please refer to FIG. 12. FIG. 12 is a bottom view of a semiconductor package according to the third embodiment of the present invention. For convenience of explanation, the same elements of FIGS. 4-6 and FIG. 12 are indicated by the same symbols. As shown in FIG. 12, a semiconductor package 30 includes a substrate 32, a plurality of bonding balls 36a and bonding balls 36b positioned on the substrate 32, and at least one dummy bonding bar 42 positioned on the substrate 32. Particularly, the bonding balls 36a are interlaced with the bonding balls 36b.

In comparison with the prior art, the present invention provides at least one dummy bonding bar 42 on the lower surface 32b of the substrate 32. Since the dummy bonding bar 42 has the planar surface 42a, there is a surface contact between the dummy bonding bar 42 and the printed circuit board 40 when the surface 42a of the dummy bonding bar 42 is connected to the printed circuit board 40. Further, because the longest side of the dummy bonding bar 42 is approximately perpendicular to the long side of the chip 34, the semiconductor package 30 can be balanced on the printed circuit board 40, thereby effectively preventing the semiconductor package 30 from inclining to one side.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A semiconductor package which is positioned on a first substrate comprising:
a second substrate having a first surface and a second surface;
a chip positioned on the first surface of the second substrate;
a plurality of first bonding balls positioned on the second surface of the second substrate and arranged in a line along a first direction for connecting the second substrate to the first substrate; and
at least a dummy bonding bar positioned on the second surface of the second substrate for connecting the second substrate to the first substrate and preventing the semiconductor package from inclining to one side.

2. The semiconductor package of claim 1 wherein the second surface has a rectangular shape, and the first direction is parallel to a long side of the second surface.

3. The semiconductor package of claim 2 wherein the longest side of the dummy bonding bar is approximately perpendicular to the long side of the second surface for preventing the semiconductor package from inclining.

4. The semiconductor package of claim 3 wherein a length of a short side of the second surface is less than 1000 μm.

5. The semiconductor package of claim 1 wherein the dummy bonding bar has a planar third surface connected to the first substrate for preventing the semiconductor package from inclining.

6. The semiconductor package of claim 1 further comprising a plurality of first bonding pads, each of which being positioned between the second surface and each of the first bonding balls, and at least a dummy bonding pad positioned between the second surface and the dummy bonding bar.

7. The semiconductor package of claim 6 further comprising a plurality of second bonding pads positioned on the second surface and a plurality of second bonding balls respectively positioned on the second bonding pads, the second bonding balls being interlaced with the first bonding balls.

8. The semiconductor package of claim 7 wherein a height of the dummy bonding bar is the same as a height of each of the first bonding balls and the second bonding balls.

9. The semiconductor package of claim 7 wherein the first bonding balls, the second bonding balls and the dummy bonding bar respectively comprise a tin (Sn) based metal containing lead (Pb), and a melting point of the tin based metal is between 180° C. and 235° C.

10. The semiconductor package of claim 9 wherein the first bonding pads, the second bonding pads and the dummy bonding pad respectively comprise a tin based metal, which contains no lead and has a melting point between 180° C. and 235° C.

11. The semiconductor package of claim 1 wherein the first substrate comprises a build-up printed circuit board, a co-fired ceramic substrate, a thin-film deposited substrate, or a glass substrate.

12. The semiconductor package of claim 1 wherein the chip is an image sensor chip.

13. A method for manufacturing a semiconductor package comprising:
providing a substrate having a first surface and a second surface;
forming a plurality of first bonding balls on the first surface of the substrate, the first bonding balls being arranged in a line along a first direction;
forming at least a dummy bonding bar on the first surface of the substrate; and
providing a chip and locating the chip on the second surface of the substrate, wherein the dummy bonding bar is utilized for preventing the semiconductor package from inclining to one side.

14. The method of claim 13 further comprising:
providing a printed circuit board and connecting the printed circuit board to the substrate by using the first bonding balls and the dummy bonding bar.

15. The method of claim 14 wherein the dummy bonding bar has a planar third surface connected to the printed circuit board for preventing the semiconductor package from inclining.

16. The method of claim 13 wherein before the first bonding balls and the dummy bonding bar are formed, the method further comprises:
forming a plurality of first bonding pads on the first surface of the substrate, the first bonding pads being arranged in a line along the first direction and the first bonding balls being respectively positioned on the first bonding pads; and
forming at least a dummy bonding pad on the first surface of the substrate, the dummy bonding bar being positioned on the dummy bonding pad.

17. The method of claim 16 further comprising:
forming a plurality of second bonding pads on the first surface of the substrate, the second bonding pads being arranged in a line along the first direction and the second bonding pads being interlaced with the first bonding pads; and
forming a second bonding ball on each of the second bonding pads.

18. The method of claim 17 wherein the first bonding balls, the second bonding balls and the dummy bonding bar respectively comprise a tin based metal containing lead, and a melting point of the tin based metal is between 180° C. and 235° C.

19. The method of claim 18 wherein the first bonding pads, the second bonding pads and the dummy bonding pad respectively comprise a tin based metal, which contains no lead and has a melting point between 180° C. and 235° C.

20. The method of claim 17 wherein a height of the dummy bonding bar is the same as a height of each of the first bonding balls and the second bonding balls.

21. The method of claim 13 wherein the first surface has a rectangular shape, and the first direction is parallel to a long side of the first surface.

22. The method of claim 21 wherein a length of a short edge of the first surface is less than 1000 μm.

23. The method of claim 21 wherein the longest side of the dummy bonding bar is approximately perpendicular to the long side of the first surface.

24. The method of claim 13 wherein the chip is an image sensor chip.

25. The method of claim 13 wherein the substrate comprises a build-up printed circuit board, a co-fired ceramic substrate, a thin-film deposited substrate, or a glass substrate.
